(19) United States
(12) Patent Application Publication
(10) Pub. No.: US 2011/0018562 A1
(43) Pub. Date: Jan. 27, 2011

(54) HIGH VOLTAGE CAPACITANCE PROBE

(76) Inventor: Filippo Galluppi, Blue Point, NY (US)

Correspondence Address: OSTROLENK FABER GERB & SOFFEN, 1180 AVENUE OF THE AMERICAS, NEW YORK, NY, 100368403, US

(21) Appl. No.: 12/840,380

(22) Filed: Jul. 21, 2010

Related U.S. Application Data
(60) Provisional application No. 61/227,145, filed on Jul. 21, 2009.

(51) Int. Cl. G01R 27/26

(52) U.S. Cl. 324/690

(57) ABSTRACT

A high voltage capacitance probe has a central conductor rod forming one capacitor electrode which is fixed to an elongated dielectric support and has a probe tip extending beyond the edge of the dielectric support. A conductive layer defining a second capacitor electrode is formed on a surface of the dielectric support and is capacitively coupled to the central conductor rod.

### RELATED APPLICATIONS

This application claims the benefit of U.S. Provisional Application No. 61/227,145, filed Jul. 21, 2009, the entire disclosure of which is incorporated by reference herein.

### FIELD OF THE INVENTION

This invention relates to the measurement of high voltages, and to a probe for connecting a high voltage node to an oscilloscope or other monitor.

### BACKGROUND OF THE INVENTION

High voltage capacitors are commonly used to couple a high voltage node, for example, one of tens of thousands of volts above ground to an oscilloscope or other measuring electronic circuit. However, where the devices or circuits to be measured are very small or the high voltage nodes are difficult to access the traditional capacitor connection cannot be used without the use of complex and expensive modifications.

In particular, when applied to miniature design technology, the necessary reduced size of the measurement instrument usually negatively affects its reliability and life and significantly increases cost.

It would be very desirable to provide a capacitive device which is inexpensive, highly reliable can be easily and safely used to couple high voltage nodes to metering apparatus and to enable the viewing and or measuring of the high voltage wave form.

### BRIEF DESCRIPTION OF THE INVENTION

In accordance with the invention, a high voltage capacitive probe is formed of a small diameter elongated conductor, such as a thin wire or rod disposed on or within an elongated dielectric body. An outer conductor is formed on a surface of the dielectric body opposite to the wire. The thin conductor extends beyond the end of the dielectric body to serve as a probe tip having the necessary stiffness to act as a probe. The central conductor and outer conductor act as capacitor plates separated by the thickness of the insulation dielectric which receives them. The capacitance of the device depends generally on the overlapping area of the central wire and outer conductor and on the dielectric constant of the insulator.

Typically a capacitance of about 5 μμf at 60 kv may be conveniently created. This probe capacitance will be connected to an external capacitor of 5000 μμf to form a capacitive divider with a 1000:1 ratio to produce a 50 v pulse to an oscilloscope from a 50 kv pulse applied to the probe end of the thin wire electrode.

In a preferred embodiment of the invention, the dielectric body is a thin elongated cylinder with a central opening formed into one end of the cylinder. A thin conductive rod is inserted into and secured within the elongated opening and an end of the wire extends out of the end of the cylinder to serve as the probe end of the device. A conductive foil is wrapped or otherwise formed around the exterior of the cylinder and is at least partly coextensive with the wire embedded within the cylinder. The diameter of the cylinder and its dielectric constant and the overlapping length of the wire and outer foil will define the probe capacitance. A thin insulation layer or wrapper may cover the cylinder and outer foil, and a grounded mesh may be wound or drawn over the thin insulation layer.

### BRIEF DESCRIPTION OF THE DRAWINGS

FIG. 1 is a partial cross-section of a first embodiment of the invention at a first stage of its manufacture.

FIG. 2 shows the structure of FIG. 1 after the application of an insulation tape and conductive screen over the device, and the application of an SMA connector to the left hand end of the device.

FIG. 3 is a top plan view of the device of FIG. 2 with an exterior insulation coating or wrap.

FIG. 4 is a cross sectional view of FIG. 2 taken across section line 4-4 in FIG. 2.

FIG. 5 is a circuit diagram showing an application of the probe of FIGS. 1, 2, 3 and 4.

FIG. 6 is a perspective view of a second embodiment of the invention.

FIG. 7 is a cross-section of FIG. 6 taken across section lines 6-6 in FIG. 6.

FIG. 8 is a cross-section of FIG. 6 taken across section lines 8-8 in FIG. 4.

FIG. 9 is a bottom view of FIG. 8, showing the foil electrode opposite the wire electrode.

### BRIEF DESCRIPTION OF THE PREFERRED EMBODIMENT

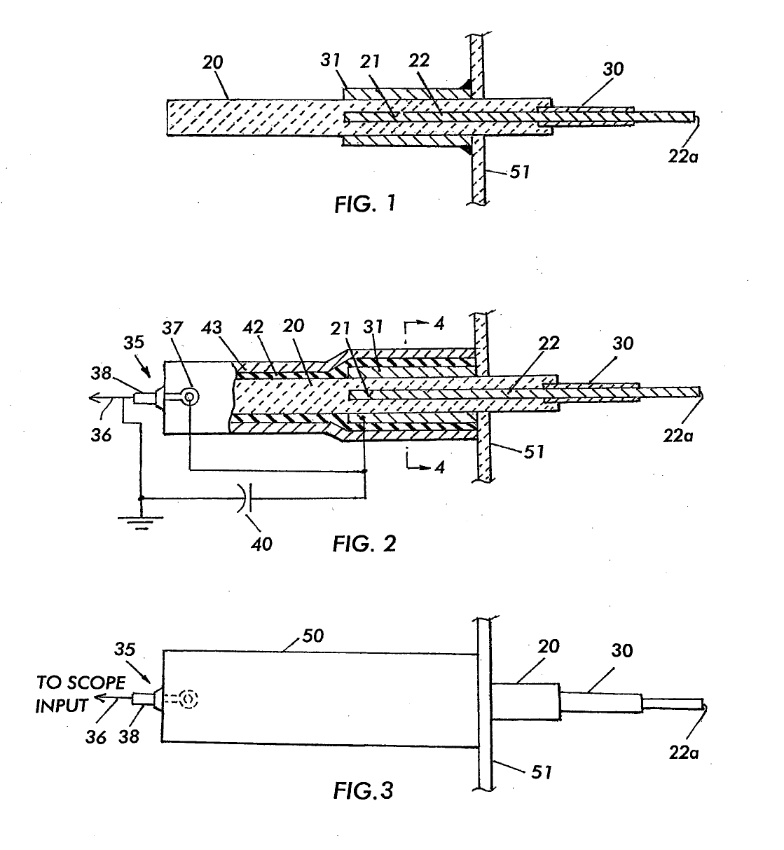

Referring first to FIGS. 1, 2, 3 and 4, the probe consists first of an elongated dielectric body 20 which has a central opening 21 drilled or otherwise formed therein. A conductive central rod or wire 22 is inserted into and suitably fixed within opening 21, as by a forced-fit or cementing, and is coaxial therewith.

In one embodiment of the invention, body 20 may be a cylindrical rod of diameter 0.46 inch and a length of 6.0 inch and may be a fiberglass resin or other dielectrics material. Opening 21 may be 3.5 inch deep and may have a diameter suitable to receive conductive wire 22. Wire 22 may be a brass or other conductive rod of diameter 0.031 inch and a length of 5 inch. Clearly, other dimensions can be used, as desired.

In the embodiment of FIGS. 1 and 2, a thin insulation sleeve 30 of any desired length surrounds the projecting end of wire 22.

A copper tape 31 next surrounds a portion of the length of rod 20 and is at least partially coextensive with rod 22 and acts as the outer electrode of the capacitive probe. Copper electrode tape 31 has a length which may typically be 2.5 inch and may be about 0.01 inch thick. Other conductive tapes or forms or coatings can be used. The capacitance of the probe of FIGS. 1 and 2 may be adjusted, for example, up to 10 μμf simply by adjusting the length of tape 31.

An SMA connector 35 is fixed to the left hand end of rod 20 in FIGS. 2 and 3. The SMA conductor 35 is a coaxial connector having an extending pin or central wire 36 connected to clip 37. Wire 36 extends through and is insulated from ground sheath 38 which is a high voltage return (HV-RTN). The electrode 31 is connected to Vₒᵤₜ pin 36 of the connector 35 and to external capacitor 40. Electrode 31 is also directly connected to terminal 37 and thus to wire 36. A shielded cable of any desired length can be connected to wire 36 of connector 35 for connection to the input of an oscilloscope or other instrument input.

To isolate the probe from external influences, a thin insulation tape 42 is wrapped around the left hand side of rod 20 and is in turn covered by a conductive layer 43, which may be a wire mesh which is insulated from electrode 31. Layer 43 is connected to the HV-RTN (ground) 38. Conductive layer 43 may be further covered with a thin insulation layer (not shown) to isolate layer 43 from outside grounds.

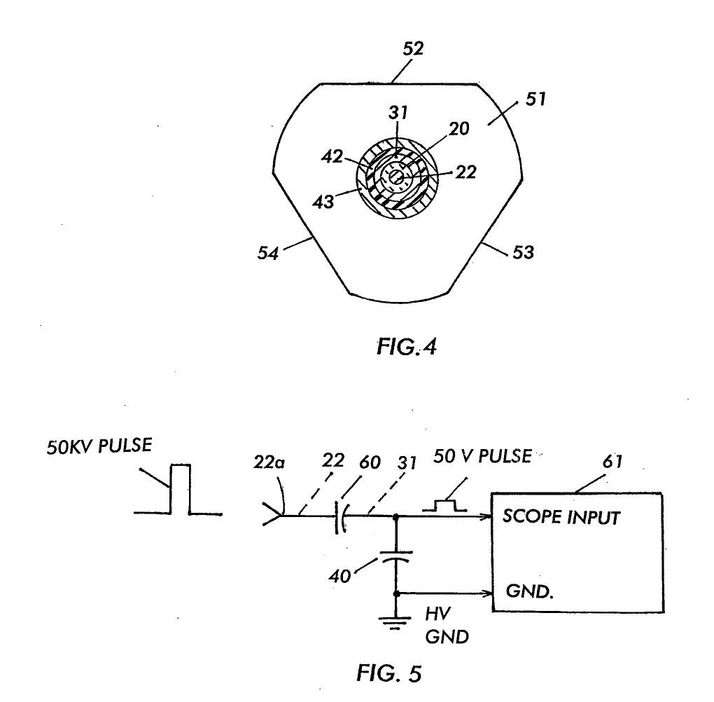

The exterior surface of the assembly of FIG. 2 is then covered with an exterior insulator coating 50 (FIG. 3) which may be a vinyl material or the like. An HV barrier 51 (FIG. 4) is also fixed to the rod 20 at the right hand end of tape 21. Barrier 51 is an insulation disk which may be ⅛ inch thick and may have a 3 inch diameter. Disk 51 may have flats 52, 53 and 54 to prevent rolling of the probe when laid flat. Barrier 51 is cemented to the rod 20 by any desired adhesive. In a preferred embodiment, the rod 20 may be machined at its right hand end to remove about 0.010 inch from its diameter. The barrier 51 can then have a central opening which will receive the reduced diameter end of rod 20 and then moved against the 0.005 inch high shoulder defined by the 0.010 inch diameter reduction and then glued in place.

FIG. 5 shows a typical circuit in which the probe of FIGS. 1, 2, 3 and 4 may be used. Thus, in FIG. 5, the probe is represented by capacitor 60 which may be 5 μμf. The external capacitor 40 may be a 5000 μμf capacitor to define a 1000:1 voltage divider circuit. The node between capacitors 60 and 40 is connected to an oscilloscope 61 input and the bottom of capacitor 40 (ground 38 of the connector 35) is connected to the oscilloscope ground.

The probe end 22a in FIG. 4 may then be touched to, for example, a node having a 50,000 volt pulse which is to be imaged on scope 61. The pulse voltage at the node between probe capacitance 60 and capacitor 40 will be a 50 volt pulse.

The divider ratio can be changed as desired. For example, if one wishes to view 50,000 volt pulses as 5 volt pulses on oscilloscope 61, the capacitance probe can be a 10 pf probe and the external capacitor 60 can be a 0.1 μf capacitor to form a 10,000:1 capacitive divider.

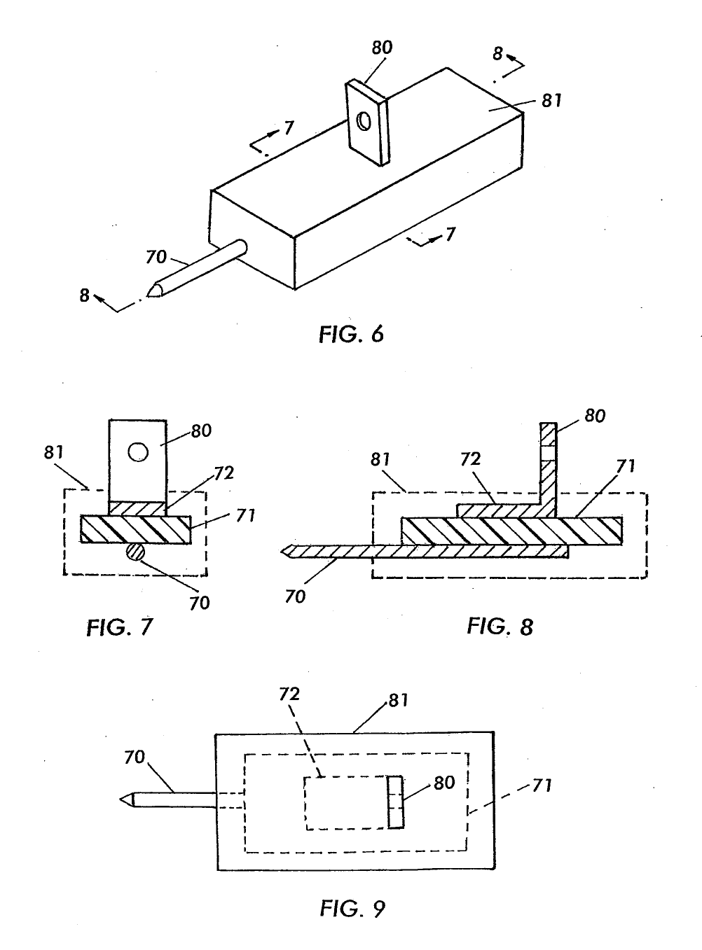

FIGS. 4 to 7 show another embodiment of the invention in which an elongated probe rod 70 is simply fixed to a flat thin dielectric sheet 71. A foil electrode 72 is formed on the surface of sheet 71 opposite to wire 70 to form the desired probe capacitor. A terminal 80 extends from foil 72 and a plastic potting enclosure 81 encloses the assembly.

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. High voltage capacitance probe comprising, in combination; an elongated conductor having at least a rigid end portion which terminates on a discrete probe point; an elongated support body of dielectric material having a surface region for receiving an supporting said elongated conductor along a portion of its length; at least a portion of said rigid end portion of said elongated conductor extending beyond an edge of said elongated support body such that said probe point can be applied to a high voltage node without interference from said support body; a conductive layer supported by said elongated support body and spaced by the material of said elongated support from said elongated conductor; said conductive layer at least partially coextensive with the portion of said elongated conductor which is in surface contact with said elongated support body, thereby to form a capacitor structure with the interposed support serving as the capacitor dielectric.

2. The probe of claim 1, wherein said conductive layer is covered by a thin protective insulation layer and said thin protective insulation layer is covered by a further conductive layer.

3. The probe of claim 1, which further includes an external terminal connected to said conductive layer.

4. The probe of claim 3, wherein said external terminal is an SMA connector fixed to the end of said elongated support body opposite from the edge receiving said rigid end portion of said elongated conductor.

5. The probe of claim 1, wherein said elongated support body is a rod having a central elongated opening receiving and surrounding said elongated conductor along said portion of its length, said conductive layer comprising a conductor disposed around the outer surface of said rod of dielectric material.

6. The probe of claim 5, wherein said elongated conductor is a thin conductive rod.

7. The probe of claim 6, wherein said conductive layer is covered by a thin protective insulation layer and said thin protective insulation layer is covered by a further conductive layer.

8. The probe of claim 6, which further includes an external terminal connected to said conductive layer.

9. The probe of claim 8, wherein said external terminal is an SMA connector fixed to the end of said elongated support body opposite from the edge receiving said rigid end portion of said elongated conductor.

10. The probe of claim 5 which further includes a thin shield disposed perpendicular to the axis of said rod and fixed to the outer surface of said rod at an axial location between the end of said conductive layer and the exposed probe portion of said thin conductor.
